(19) United States
(12) Patent Application Publication
(10) Pub. No.: US 2025/0172850 A1
(43) Pub. Date: May 29, 2025

(54) USING MICRO/NANO RESONATORS WITH PHOTONS

(71) Applicant: BRITISH TELECOMMUNICATIONS PUBLIC LIMITED COMPANY, London, Greater London (GB)

(72) Inventors: Robert HERCOCK, London (GB); Catherine WHITE, London (GB)

(21) Appl. No.: 18/841,874

(22) PCT Filed: Feb. 7, 2023
(86) PCT No.: PCT/EP2023/052916

§ 371 Date: Aug. 27, 2024

(30) Foreign Application Priority Data
Mar. 1, 2022 (GB) 2202806.2

(51) Int. Cl. G02F 1/365; G02B 6/02; G02F 1/355; H03H 9/02; H03H 9/145; H03H 9/25; H04B 10/70

(52) U.S. Cl. CPC G02F 1/365; G02B 6/02328; G02F 1/3551; H03H 9/02968; H03H 9/14502; H03H 9/25; H04B 10/70

(57) ABSTRACT

A method of exchanging quantum information between a photon and a micro/nano scale resonant structure is provided. The method comprises providing the resonant structure (15) in an optical waveguide (10). The method further comprises passing a photon (18) through the resonant structure in the optical waveguide. The method also comprises applying a driving signal (17) to the resonant structure to cause phonic oscillation of the resonant structure and to modulate a wavelength of the photon such that the passing the photon through the resonant structure results in an exchange of quantum information between the photon and a quantum state in a phonon of the resonant structure.

The present disclosure relates to exchanging quantum information between a photon and a micro/nano scale resonator structure. The present disclosure also relates to using two entangled micro/nano scale resonator structures to entangle two photons.

### BACKGROUND

Recent research in micro-scale entanglement of physical structures, has been a revolution in our understanding of the entanglement process. Entanglement was previously considered to only occur at the atomic quantum scale. However, as shown in L. Mercier et al. “Quantum mechanics-free subsystem with mechanical oscillators” Science, Vol. 372, issue 6542, pages 625-629 and S. Kotler et al. “Direct observation of deterministic macroscopic entanglement” Science, vol. 372, issue 6542, pages 622-625 it is possible to create a quantum entangled state across physical scale structures, (i.e., with billions of atoms). Existing micro-scale quantum entanglement systems have utilised aluminium or other metal drum structures to create a resonant cavity. These are then driven to an entangled (position) state via micro-wave frequency photon stimulation.

However, applications of these phenomena for quantum computing, quantum communication, and quantum cryptography (such as quantum key distribution) have not been considered. In addition, there has been no consideration of how these phenomena can be combined to improve entanglement generation, two-qubit gates etc.

The examples described herein are not limited to examples which solve problems mentioned in this background section.

### SUMMARY

Examples of preferred aspects and embodiments of the invention are as set out in the accompanying independent and dependent claims.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

A method of exchanging quantum information between a photon and a micro/nano scale resonant structure is provided. The method comprises providing the resonant structure in an optical waveguide; passing a photon through the resonant structure in the optical waveguide; and applying a microwave driving signal to the resonant structure to cause phonic oscillation of the resonant structure and to modulate a wavelength of the photon such that the passing the photon through the resonant structure results in an exchange of quantum information between the photon and a quantum state in a phonon of the resonant structure. The method thus provides a method of transferring quantum information from a photon into a resonant structure. This enables the resonant structure to be used as a quantum memory or buffer. The method can also be used to transfer quantum information from the resonant structure to the photon.

In one example of the above method the optical waveguide is a hollow core optical fibre. In some examples, the hollow core optical fibre may comprise, contain or include a piezoelectric material or the hollow core optical fibre may comprise, contain or include a piezoelectric layer. In some examples, the optical fibre comprising a piezoelectric material comprises the optical fibre having a piezoelectric component as a feature or inclusion in the fibre. In some examples the piezoelectric component or element is part of the internal structure of the hollow core optical fibre.

The resonant structure comprises a section of the hollow core optical fibre wherein the section of the hollow core optical fibre comprises a metallic film wherein the metallic film either coats or is internal to the section of the hollow core optical fibre and wherein the metallic film allows acoustic phonons to be created by excitation using microwaves. The method thus allows hollow core optical fibres to be used as resonators and enables hollow core optical fibres to go from being passive photon conduits to active computing elements. The metallic film can take any suitable form and may also comprise for example metallic tape or other layers of metallic material.

The above-mentioned metallic film may be a surface acoustic wave modulator in the form of an interdigital transducer. This means photons passing through the hollow core optical fibre will experience a wavelength or phase modulation due to the surface acoustic waves from the interdigital transducer.

In another example of the above method the optical waveguide is a photonic cavity fabricated on a surface of a substrate; and the resonant structure is a cavity fabricated on the surface of the substrate. This enables a quantum memory/buffer to be formed in photonic cavity based systems. In some examples, the cavity that forms the resonant structure may be patterned with a metallic pattern in the form of an interdigital transducer. Although other ways of generating surface acoustic waves may also be used.

In some examples, the above method may further comprise stressing the resonant structure using an applied electric field, magnetic field or mechanical deformation to change the properties of the resonant structure; and passing a second photon through the resonant structure wherein passing the second photon through the resonant structure causes release of the quantum state stored in the resonant structure. This enables the resonant structure to be used as a buffer or memory since in a first instance a quantum state can be transferred to the resonant structure from a first photon while in a second instance the quantum state can be transferred from the resonant structure to a second photon.

Different resonant structures may be used as part of the above method. For example the resonant structure may comprise a structured macromolecule or nanoscale crystal such as a carbon nanotube, buckyball or nanowire or a nano-scale cavity on the surface of the optical waveguide or within a layer of the optical waveguide. In some examples, applying a microwave driving signal to the resonant structure comprises applying the microwave driving signal to the resonant structure such that the structured macromolecule, nanoscale crystal or cavity absorbs the photon and stores a quantum state of the photon. Resonant structures of this form can be used with both optical/photonic cavities and hollow core optical fibres. Resonant structures of this form provided an additional way of controlling an interaction between a photon and a resonant structure in a wave guide.

A system for acting as a quantum memory, quantum buffer or quantum interface is provided. The system comprises an optical waveguide; a micro/nano scale resonant structure within the optical waveguide; and a driving system configured to apply a microwave driving signal to the resonant structure and cause phonic oscillation of the resonant structure and thus modulate a wavelength of a photon passing through the resonant structure and hence exchange quantum information between the photon and a quantum state in a phonon of the resonant structure. As a quantum state of a photon can be transferred to the resonant structure of the system, the system can be used as a quantum memory, quantum buffer or quantum interface in accordance with the methods described above.

In some examples of the system, the optical waveguide is a hollow core optical fibre. In some examples, the hollow core optical fibre may comprise a piezoelectric material or the hollow core optical fibre may comprise a piezoelectric layer. The resonant structure comprises a section of the hollow core optical fibre wherein the section of the hollow core optical fibre comprises a metallic film wherein the metallic film either coats or is internal to the section of the hollow core optical fibre and wherein the metallic film allows acoustic phonons to be created by excitation using microwaves. This enables hollow core optical fibres to be used as resonators and enables hollow core optical fibres to go from being passive photon conduits to active computing elements. The metallic film can take any suitable form and may also comprise for example metallic tape or other layers of metallic material.

In some examples, the metallic film mentioned above is a surface acoustic wave modulator in the form of an interdigital transducer. This means photons passing through the hollow core optical fibre will experience a wavelength or phase modulation due to the surface acoustic waves from the interdigital transducer.

In other examples of the system the optical waveguide is a photonic cavity fabricated on a surface of a substrate; and the resonant structure is a cavity fabricated on the surface of the substrate. This enables a quantum memory/buffer/interface to be formed in photonic cavity based systems. In some examples, the cavity that forms the resonant structure may be patterned with or take the form of a metallic pattern in the form of an interdigital transducer. Although other ways of generating surface acoustic waves may also be used.

A method of entangling two photons is provided. The method comprises providing a first micro/nano scale resonant structure in a first optical waveguide; providing a second micro/nano scale resonant structure in a second optical waveguide; entangling the first and second resonant structures; passing a first photon through the first resonant structure of the first optical waveguide; and passing a second photon through the second resonant structure of the second optical waveguide. This provides a convenient method for controllably entangling two photons for use in either two-qubit gates or quantum communication or quantum cryptography applications.

In some examples entangling the first and second resonant structures comprises driving the first and second resonant structures via microwave frequency photon stimulation. This provides a convenient way of entangling the first and second resonant structures without excess noise.

In examples of the entangling method, the first optical waveguide is a first hollow-core optical fibre, and the second optical waveguide is a second hollow-core optical fibre. In some examples, the first and second hollow-core optical fibres may comprise a piezoelectric material or the first and second hollow-core optical fibres may comprise a piezoelectric layer. The first resonant structure comprises a first section of the first hollow core optical fibre wherein the first section of the first hollow core optical fibre comprises a first metallic film wherein the first metallic film either coats or is internal to the first section of the first hollow core optical fibre and wherein the first metallic film allows acoustic phonons to be created by excitation using microwaves. The second resonant structure comprises a second section of the second hollow core optical fibre wherein the second section of the second hollow core optical fibre comprises a second metallic film wherein the second metallic film either coats or is internal to the second section of the second hollow core optical fibre and wherein the second metallic film allows acoustic phonons to be created by excitation using microwaves. This enables hollow core optical fibres to go from being used as passive photon conduits to elements for performing quantum entanglement. This also enables in fibre generation of quantum entanglement for either two-qubit quantum gates or other communication or cryptographic applications. The metallic film can take any suitable form and may also comprise for example metallic tape or other layers of metallic material.

In some examples, the first metallic film and the second metallic film are surface acoustic wave modulators in the form of interdigital transducers. This means photons passing through the hollow core optical fibre will experience a wavelength or phase modulation due to the surface acoustic waves from the interdigital transducer.

In some examples, passing the first photon through the first resonant structure results in the first photon experiencing a wavelength or phase modulation driven by phonic oscillation of the first section of the first hollow-core optical fibre. Likewise, passing the second photon through the second resonant structure results in the second photon experiencing a wavelength or phase modulation driven by phonic oscillation of the second section of the second hollow-core optical fibre. The method may further comprise varying a frequency of a driving signal of the first resonant structure and the second resonant structure to modulate a wavelength of the first photon and the second photon respectively. This aids in ensuring the entangled state of the resonant structures is transferred to the photons.

In other examples the first optical waveguide is a first optical cavity structure fabricated on a surface of a substrate and the second optical waveguide is a second optical cavity structure fabricated on the surface of the substate. In this case the first resonant structure can be a first metal cavity in the first optical cavity structure; and the second resonant structure can be a second metal cavity in the second optical cavity structure. This enables photons to be entangled in photonic cavity based systems. In some examples, the cavities that form the resonant structures may be patterned with a metallic pattern in the form of an interdigital transducer or otherwise take the form of an interdigital transducer. Although other ways of generating surface acoustic waves may also be used.

When the waveguides are optical cavity structures, the method may in some examples further comprise outputting the first photon from the first resonant structure to a first optical fibre; and outputting the second photon from the second resonant structure to a second optical fibre. This enables a combination of optical cavities and optical fibres to be used when entangling photons.

In the above examples, the first resonant structure may be a micro-scale resonant structure and a first surface of the first micro-scale resonant structure may be decorated with nano-scale features. Similarly, the second resonant structure may be a micro-scale resonant structure and a second surface of the second micro-scale resonant structure may be decorated with nano-scale features. This may enable stronger couplings between the resonant structures and the photons.

A system for entangling photons is provided. The system comprises a first optical waveguide; a second optical waveguide; a first micro/nano scale resonant structure in the first optical waveguide; a second micro/nano scale resonant structure in the second optical waveguide; and a driving system configured to apply a microwave incident signal to the first resonant structure and the second resonant structure and hence excite and entangle the first and second resonant structures. This provides a system for entangling photons by transferring entanglement from the first and second resonant structures into the first and second photon. This can provide a convenient way of generating entanglement for two-qubit gates and can also provide entanglement for quantum communication and quantum cryptographic applications.

In some examples of the system the first optical waveguide is a first hollow-core optical fibre; and the second optical waveguide is a second hollow-core optical fibre. In some examples, the first and second hollow-core optical fibres may comprise a piezoelectric material or the first and second hollow-core optical fibres may comprise a piezoelectric layer. The first resonant structure comprises a first section of the first hollow core optical fibre wherein the first section of the first hollow core optical fibre comprises a first metallic film wherein the first metallic film either coats or is internal to the first section of the first hollow core optical fibre and wherein the first metallic film allows acoustic phonons to be created by excitation using microwaves. The second resonant structure comprises a second section of the second hollow core optical fibre wherein the second section of the second hollow core optical fibre comprises a second metallic film wherein the second metallic film either coats or is internal to the second section of the second hollow core optical fibre and wherein the second metallic film allows acoustic phonons to be created by excitation using microwaves. As such, the system can be used in/with optical fibres and the optical fibres can go from being passive photon conduits to a means for generating entanglement. The metallic film can take any suitable form and may also comprise for example metallic tape or other layers of metallic material.

In some examples, the first metallic film and the second metallic film are surface acoustic wave modulators in the form of interdigital transducers. This means photons passing through the hollow core optical fibre will experience a wavelength or phase modulation due to the surface acoustic waves from the interdigital transducer.

In other examples, the first optical waveguide is a first optical cavity structure fabricated on a surface of a substrate; and the second optical waveguide is a second optical cavity structure fabricated on the surface of the substate. The first resonant structure may then be a first metal cavity in the first optical cavity structure; and the second resonant structure may then be a second metal cavity in the second optical cavity structure. This enables photons to be entangled in photonic cavity based systems. In some examples, the cavities that form the resonant structures may be patterned with a metallic pattern in the form of an interdigital transducer or may themselves take the form of an interdigital transducer. Although other ways of generating surface acoustic waves may also be used.

In some examples of the system for entangling photons, the first resonant structure is a micro-scale resonant structure and a first surface of the first micro-scale resonant structure may be decorated with nano-scale features; and the second resonant structure is a micro-scale resonant structure and a second surface of the second micro-scale resonant structure may be decorated with nano-scale features. This may enable stronger couplings between the resonant structures and the photons.

It will also be apparent to anyone of ordinary skill in the art, that some of the preferred features indicated above as preferable in the context of one of the aspects of the disclosed technology indicated may replace one or more preferred features of other ones of the preferred aspects of the disclosed technology. Such apparent combinations are not explicitly listed above under each such possible additional aspect for the sake of conciseness.

Other examples will become apparent from the following detailed description, which, when taken in conjunction with the drawings, illustrate by way of example the principles of the disclosed technology.

### BRIEF DESCRIPTION OF THE DRAWINGS

FIG. 1 shows an example system for exchanging quantum information between a resonant structure in a hollow core optical fibre and a photon;

FIG. 2 shows an example system for exchanging quantum information between a resonant structure in a photonic/optical cavity and a photon;

FIG. 3 is a flowchart showing a method for exchanging quantum information between a resonant structure in a waveguide and a photon;

FIG. 4 shows a system for entangling two photons using resonant structures in optical fibres;

FIG. 5 shows a system for entangling two photons using resonant structures in photonic/optical cavities; and

FIG. 6 is a flowchart showing a method for entangling two photons using resonant structures in waveguides.

The accompanying drawings illustrate various examples. The skilled person will appreciate that the illustrated element boundaries (e.g., boxes, groups of boxes, or other shapes) in the drawings represent one example of the boundaries. It may be that in some examples, one element may be designed as multiple elements or that multiple elements may be designed as one element. Common reference numerals are used throughout the figures, where appropriate, to indicate similar features.

### DETAILED DESCRIPTION

The following description is made for the purpose of illustrating the general principles of the present technology and is not meant to limit the inventive concepts claimed herein. As will be apparent to anyone of ordinary skill in the art, one or more or all of the particular features described herein in the context of one embodiment are also present in some other embodiment(s) and/or can be used in combination with other described features in various possible combinations and permutations in some other embodiment(s).

The application relates to enhancing the ability to frequency modulate photonic signals and simplify the production of entangled photons. This application describes creating a controlled phonon to photon interaction within hollow core fibre, (or on-silicon structure), in order to enable a resonant structure to function as a quantum memory. In addition, this application takes advantage of recent developments in micro-scale entanglement and utilises resonating structures as a means of modulating photonic signals. The application describes achieving this either through waveguides comprising hollow core fibre resonators or through on-silicon fabrication of resonator structures. Each of these two ideas have advantages for specific applications. In terms of development, it is likely that the photonic integrated circuits may be more suitable for device applications such as quantum repeaters. However, using direct fibre resonators, could be more easily integrated into current fibre technologies. This application outlines several techniques for the realisation of each idea.

This application describes a means of achieving a stable quantum state within a hollow core fibre optical system. Alternatively, the state may be induced within a photonic/optical cavity fabricated on the surface of a substrate made of a solid-state material such as silicon, germanium, lithium niobate or indium phosphide. In addition, the application provides a means of exchanging quantum information between resonant structures in an optical waveguide and the photons travelling in the waveguide. These resonant structures make use of quantum mechanical resonance states (excitation of phonons) to store quantum information. These acoustic waves are, in the quantum limit, be quantised excitations, which in the limit of quantum mechanics may obey the properties of quantum states; including superposition and entanglement. (These may be optical phonon states or acoustic phonon states, depending on the variant of the implementation). Further, the application describes a means of coupling these resonant structures between waveguides, enabling the establishment of entangled states between waveguides, and also entanglement swapping between waveguides. In particular, by excitation of two resonant microstructure based quantum memories in adjacent waveguides (which may be achieved using a microwave source, if an interdigitated metallic pattern is printed), two quantum memories may be prepared in an entangled state. When photons in each waveguide pass the quantum memories, the entangled state may be transferred to the two photons.

In more detail, this application relates to using microscale or nanoscale resonator structures within waveguides to control quantum information present in photonic qubits. A qubit (or quantum bit) is a two-level system and is the quantum version of the classic bit, in that it is the basic unit of quantum information. Unlike classical bits, a qubit can be in a superposition of both states of the two-level system at once. Hence, a qubit can be considered to be in a superposition of zero and one. This, combined with entanglement, can lead to speed-ups compared to classical computing when solving certain problems. In optical/photonic quantum systems a qubit can take the form of a single photon where the two-levels can be, for example in frequency, phase or polarization. Although other forms of representing qubits or qudits (d-level systems) are also known. As well as finding use in optical quantum computing, photonic qubits/qudits can be used in quantum communication and quantum cryptographic applications where the qubits/qudits may be transported or teleported.

A first example of this application relates to using a resonant mechanical structure at a micro-scale to act as the substrate for systems providing a means for holding quantum information both at rest and in transit and in one example, to the use of hollow core fibre optics to act as resonant pipes or to act as the substrate or superstructure for the resonant mechanical structure which interacts with the modes of light (photonic qubits) within the hollow core fibre. In the first example of this application one or more microscale or nanoscale resonator structure can be used to transfer a quantum state between a photon and the resonator structure. This enables the resonator structure to be used as a buffer for temporarily storing the state from a photon and also enables the resonator structure to be used as an interface between photonic qubits and, via the resonator structure, other forms of qubit. Using the resonator structure as a buffer can enable the state of a photon to be stored temporarily, for example, when waiting for a second photon. Using the resonator structure as an interface enables information in photonic qubits used for transportation or cryptography etc. to be transferred to other forms of qubit which may then be used for computation. In addition, the first example may provide for multiple resonant structures within the waveguide that act as stores of quantum information (e.g. quantum memories).

A second example builds on the ideas in the first example to provide additional advantages of transferring a state between photons and resonant structures. In this second example, first and second microscale or nanoscale resonator structures can be entangled. A first photon is then passed through the first microscale or nanoscale resonator structure and a second photon is passed through the second microscale or nanoscale resonator structure. This results in the entangled state of the first and second microscale or nanoscale resonator structures being passed to the first and second photon and hence entanglement of the photons. Using two entangled resonator structures to transfer entanglement to photons can enable a two-qubit gate to be built for photonic qubits. In addition, the entangled resonator structure can be used to generate entanglement between photons for quantum communication and quantum cryptographic applications.

In both the first and second example, the resonant mechanical structure device can be spliced, etched, deposited, mounted, or patterned into a waveguide such as a hollow core fibre.

The resonant mechanical structure device can include a region, which exchanges quantum information with photons wherein the region can act as a quantum memory. The resonant mechanical structure device can be a structure micro-metallic disk or 2d shape or a cavity. The resonant mechanical structure can be triggered by changing the applied electric field or by an applied microwave to release a photon carrying the quantum information.

In the first example, a system and method for exchanging quantum information between resonant structures in an optical waveguide and the photons travelling in the waveguide is provided. These resonant structures make use of quantum mechanical resonance states (excitation of phonons) to store quantum information in the form of acoustic waves. These acoustic waves are, in the quantum limit, quantised excitations, which in the limit of quantum mechanics obey the properties of quantum states; including superposition and entanglement. These may be optical phonon states or acoustic phonon states, depending on the variant of the implementation. The waveguide may be a traditional waveguide such as an optical fibre or a waveguide on a photonic integrated circuit such as an indium phosphate system

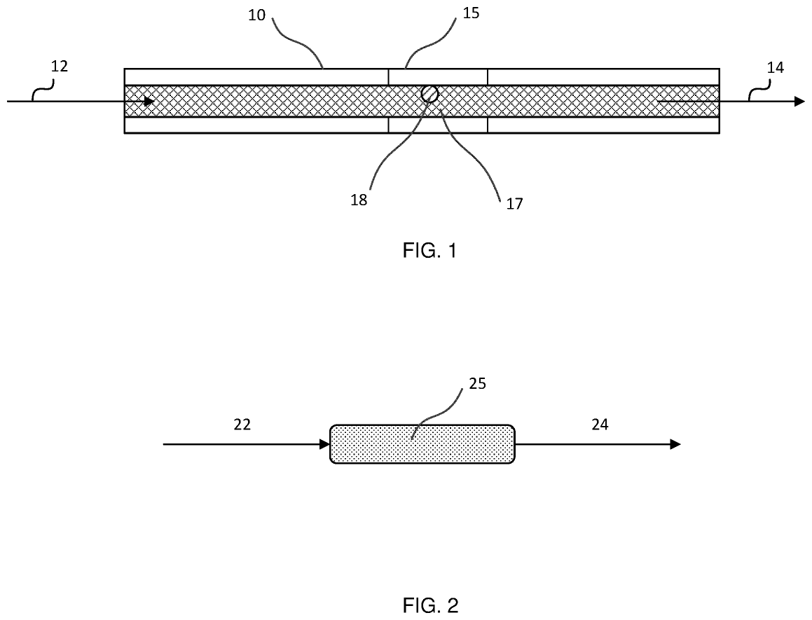

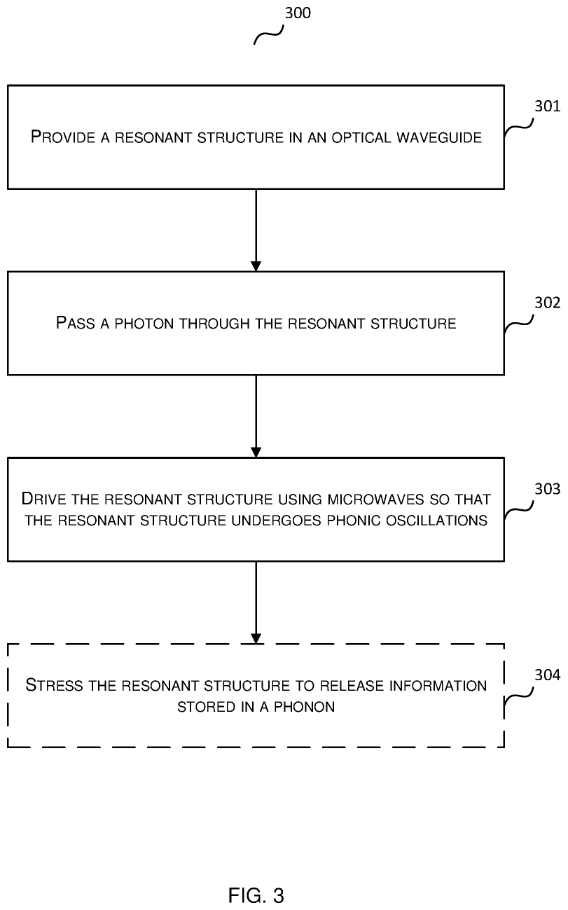

FIG. 1 shows an example of such a system for wherein the optical waveguide comprises a fibre such as a hollow-core optical fibre. FIG. 2 shows an example of such a system wherein the optical waveguide comprises a photonic/optical cavity fabricated on a surface of a substrate of a surface made of a solid-state material such as silicon, germanium, lithium niobate or indium phosphide. FIG. 3 is a flow chart showing a method of using resonant structures in/on optical waveguides as a buffer, memory and/or quantum interface.

FIG. 1 shows an optical fibre 10 wherein light is input to the optical fibre 10 at arrow 12 and light is output from the optical fibre 10 at arrow 14. The optical fibre 10 shown in FIG. 1 is a hollow core optical fibre. Examples of hollow core optical fibres that can be used with the example in FIG. 1 include nested anti-resonant nodeless fibres (NANF) and fibres based on photonic crystals. It is known that phonon to photon interaction is common in normal hollow-core optical fibres, and this typically creates optical noise. FIG. 1 shows creating controlled phonon to photon interactions in a hollow core optical fibre to enhance optical signal properties and to enable the hollow core optical fibre to be used as a buffer and/or interface between different quantum systems.

To this end, the hollow core optical fibre 10 comprises a micro/nano structure or a structure array 15 in/on the walls of a section of the hollow core optical fibre 10. The micro/nano structure is configured to act a surface acoustic wave modulator. This micro/nano structure is driven by an incident microwave signal, such as microwave field 17, to cause the section of the hollow core optical fibre 10 to act as a resonant pipe and hence a resonant structure. In other examples, the section of the hollow core optical fibre 10 acts as a substrate or superstructure for the resonant micro/nano structure which interacts with the modes of light (photonic qubits) within the hollow core fibre This resonant structure can store quantum information in the form of the excitation of phonons i.e. in quantum mechanical resonance states. Photons 18 passing through the hollow core optical fibre 10 and the section of the hollow core optical fibre 10 will experience a wavelength or phase modulation driven by the phonic oscillation of the section of the hollow core optical fibre 10. By varying the driving signal frequency of the microwaves it becomes possible to modulate the wavelength of the photons 18. The length of each micro/nano structure may be varied to create specific resonant frequencies in the waveguide. Some examples may use an array of varying length micro/nano structures, to provide filtering or selection of multiple frequencies in parallel.

In some examples the micro/nano structure 15 can be a structured macromolecule or nanoscale crystal, a nanoscale or microscale molecular disk, rod or dot, such as a graphene flake, a carbon or boron nanotube or silicon nanowire, or a buckyball. In other examples the micro/nano structure 15 may be doped atoms within a glass of the optical fibre 10 or trapped ions or atoms inside a cavity of the optical fibre 10. The micro/nano structure 15 may also be an anti-resonant structure within an anti-resonant nodeless fibre or a cell within a photonic crystal-based fibre. The micro/nano structure 15 can be included within the sidewalls and/or cells of the hollow core optical fibre 10. In some examples, the micro/nano structure 15 is patterned with a metallic structure that allows acoustic phonons to be created by excitation using microwaves and may also enable the micro/nano structure to emit microwave photons. Thus, the micro/nano structure 15 can act as an interdigital transducer wherein interdigital transducers convert electrical/microwave signals to surface acoustic waves and hence resonance states in the form of excitation of phonons. In other examples, the micro/nano structure 15 is configured to acts as an interdigital transducer without the need for patterned metallic structure provided the micro/nano structure 15 supports surface acoustic waves. As mentioned above, since the micro/nano structure acts as an interdigital transducer, an incident microwave signal, such as microwave field 17, can be used to cause the micro/nano structure 15 and/or the section of the hollow core optical fibre to act as a resonant structure. Photons 18 passing through the hollow core optical fibre 10 will experience a wavelength or phase modulation driven by the phonic oscillation of the resonant structure. By varying the driving signal frequency of the microwaves it becomes possible to modulate the wavelength of the photons 18.

In other examples, the micro/nano structure 15 can comprise a metallic film or structured coating either coating or internal to the optical fibre 10. In these examples, the optical fibre 10 either may have a piezoelectric layer or a piezoelectric material may be used, optionally along with other materials, in the manufacture of the optical fibre 10. In this case, the micro/nano structure 15 acts as a surface acoustic wave modulator and is patterned as an interdigital transducer wherein, as mentioned above, an interdigital transducer converts electrical/microwave signals to surface acoustic waves. In some examples, the metallic film/structured coating may take the form of metallic patterns such as interdigitated rings or a grid which may consist of interlaced conductive elements.

Existing hollow core optical fibres have many internal cross-section designs that vary in number and configuration of the active and cavity sections. The region of the fibre used as a micro/nano resonant structure could either be in the core hollow zone, or across the whole fibre cross-section. In addition, by applying varying lengths of metal film to sub-sections of the same fibre, in the same region, then by applying a single driving resonant signal, the fibre will resonate at multiple wavelengths in parallel. This would allow the optical signal in the fibre to have different frequencies selected, or to filter out unwanted frequencies.

In order to use the system shown in FIG. 1 as a quantum buffer or interface the microwave input to each micro/nano structure 15 is driven such that passing a photon 18 through the micro/nano structure results in an exchange of information between the photon 18 and the quantum states in phonons in the surface of the optical fibre 10 that are a result of the excitation of the micro/nano structure 15. By varying the driving signal frequency of the micro/nano structures, it becomes possible to modulate the wavelength of the transmitted photons This enables an input from the photons 18 into the buffer. In order to release the quantum information from the micro/nano structure the micro/nano buffer is stressed by applying an electric or magnetic field or a mechanical deformation (via the piezoelectric layer/piezoelectric material) which changes the properties of the micro/nano structure causing the release of the quantum state when stimulated by an incident photon which is travelling through the hollow core optical fibre 10.

The example with respect to FIG. 1, has photons interact using a surface acoustic wave (SAW) on a hollow core or photonic crystalline fibre. The SAW is induced locally. This enables capture of the quantum properties of the SAW. Lithography and etching can be used to create devices such as micro resonators (the above-mentioned micro/nano structures) on the inside of a hollow core optical fibre.

FIG. 2 shows another example of a system or exchanging quantum information between resonant structures in an optical waveguide and the photons travelling in the waveguide. In the example shown in FIG. 2, the optical waveguide comprises a photonic cavity fabricated on a surface of a substrate made of a solid-state material such as silicon, germanium, lithium niobate or indium phosphide. Thus, the waveguide may comprise a guided system that involves free space sections, in which lenses, diffraction gratings and collimators are used to direct light, and the light may interact with surfaces (for example reflective or refractive) which may be involved in redirecting the light.

FIG. 2 shows light 22, 24 passing through a micro/nano structure 25 comprising a resonator 25. The resonator 25 may be a cavity that is fabricated directly on the surface of the substrate. The resonator 25 may thus be metallic coupled disks or graphene flakes which are bounded to the surface of the waveguide by nano-couplers or micro-couplers (lengths of material) or may be weakly bonded by surface forces such as Van der Walls. In other examples, the resonator 25 may be structured macromolecules or nanoscale crystals such as buckyballs which may be trapped on a surface of the waveguide or within a layer of the waveguide, for example as peapod nanotubes. The length of each micro/nano structure may also be varied to create specific resonant frequencies in the waveguide. Some applications may use an array of varying length micro/nano structures, to provide filtering or selection of multiple frequencies in parallel.

As described with respect to FIG. 1, the micro/nano structure 25 can comprise/take the form of or otherwise be provided with/decorated with/coated with a pattern that forms an interdigital transducer. This pattern may be a metallic pattern in the form of an interdigital transducer. However, other ways of generating surface acoustic waves may also be possible.

As described with respect to FIG. 1, the cavities and/or other resonator structures in FIG. 2 may be driven by an incident microwave signal to generate a surface acoustic wave. A photon may be passed through or over the resonator 25 while the resonator 25 is being excited into a phonic state using microwaves. This results in an interaction between the photon and a phonon in the resonator 25 which results in an exchange of quantum information and/or energy between the photon and the phonon. The state of the photon can then be stored in the state of the phonon. The quantum state stored in the phonon can later be released by applying an electric or magnetic field to stress the material forming the resonator 25. This changes the properties of the resonator 25 which causes release of the quantum state when stimulated by a second photon passing through the resonator 25 and waveguide.

The example of FIG. 2 includes the idea of a silicon photonic waveguide which passes the photons over a surface acoustic wave (SAW) where the quantum information can be exchanged. It would work with single photons or could include configurations designed to exchange information from photons that are part of an entangled pair or group. The SAW on a micro resonator (micro/nano structure) could prepare the photon, which could then be routed by the silicon waveguide to a nanocavity where it would be stored. The storage of the quantum information could be on another metal micro resonator, which would then exchange the information back to a photon when one was generated, e.g. from an optical nanocavity, and routed over the resonator via the waveguide (possibly with several reflections to optimise exchange).

As mentioned above, the micro/nano structure can be considered to be a resonant structure. In order to obtain a stronger interaction between optical photons used in telecommunication systems (with wavelength typically in the range 600-1700 nm) and the mechanically resonant micro/nano structures, some implementations provide smaller features, such as nanoscale cavities and hence use nanostructures. In some implementations the mechanical resonators are at the nanoscale, therefore affording stronger coupling with the optical signal. In other implementations the large (microstructure) resonator interacts with nanoscale features, for example by changing the separation of a surface pattern on the resonator, or the distribution of the cavities.

In the examples shown in both FIG. 1 and FIG. 2 the micro/nano structure may be resonant structure that may be a whole or part of the cross section of the waveguide. For example, the resonant structure may be a subcomponent of the cross section of the waveguide, such as a cell within the photonic crystal, or an anti-resonant structure within the NANF. In other examples the resonant structure may be a nanoscale cavity in the surface of the waveguide. In further examples, the resonant structure may be a structured macromolecule or nanoscale crystal, a nanoscale or microscale molecular disk, rod or dot, such as a graphene flake, a carbon or boron nanotube or silicon nanowire, or a buckyball. The resonant structure may be an inclusion within the sidewalls of the waveguide (e.g. within the cells of the hollow core structure). The resonant structure may be patterned with a metallic structure that allows acoustic phonons to be created by excitation using microwaves. This structure may also emit microwave photons. This may be a means of coupling two adjacent resonant structures and exchanging quantum information or creating entanglement between the states.

FIG. 3 is a flowchart describing a method 300 for using the systems shown in FIG. 1 and FIG. 2. In step 301 a resonant structure is provided in an optical waveguide. As discussed above, the waveguide may be a hollow core optical fibre 10 or a photonic cavity fabricated on the surface of a substrate. When the waveguide is a hollow core optical fibre 10, then the resonant structure can comprise: a portion of the hollow core optical fibre that has, optionally been adapted to have piezoelectric properties, and which is patterned with a metallic film; a nanoscale or a structured macromolecule or nanoscale crystal, a microscale molecular disk, rod or dot, such as a graphene flake; a carbon or boron nanotube or silicon nanowire; a buckyball; doped atoms within a glass of the optical fibre 10; or trapped ions or atoms inside a cavity of the optical fibre 10. When the waveguide is a photonic cavity fabricated on the surface of a substrate, then the resonant structure can comprise: a structured macromolecule or nanoscale crystal, a cavity that is fabricated directly on the surface such as a metallic coupled disk or graphene flake; or buckyballs which may be trapped on a surface of the waveguide or within a layer of the waveguide.

In step 302, a photon is passed through the resonant structure in/on the optical waveguide. In some examples, and depending on the form of the resonant structure, the photon may be passed over or under the resonant structure. In other examples, the photon can be reflected from a surface of the resonant structure rather than passing through a cavity/resonant structure.

In step 303, which may occur at the same time or before step 302, the resonant structure which is a micro or nano structure is driven using microwaves so that the resonant structure undergoes phonic oscillation. This results in a surface acoustic wave on/in the resonant structure and excitation of the resonant structure into phonic states. Since surface acoustic waves enable photon to phonon modulation, by varying the driving signal frequency of the resonators, this enables modulation of the wavelength of the transmitted photons. This enables an exchange of information between the photon and a phonon in the resonant structure undergoing phonic oscillation. This enables the resonant structure to be used to temporarily store the quantum information from the photon and/or to act as an interface, since the quantum information from the photon (and now in the phonon) can then be transferred to another form of qubit.

In optional step 304, the resonant structure is being used as a temporary store and/or a buffer. Therefore, the quantum information transferred into the phonon needs to be transferred back to a photon. In order to do this, an electric or magnetic field is applied to the resonant structure to stress the resonant structure and change the properties of the resonant structure. This causes the release of the information stored in the phonon when stimulated by another photon passing through the resonant structure and hence the waveguide.

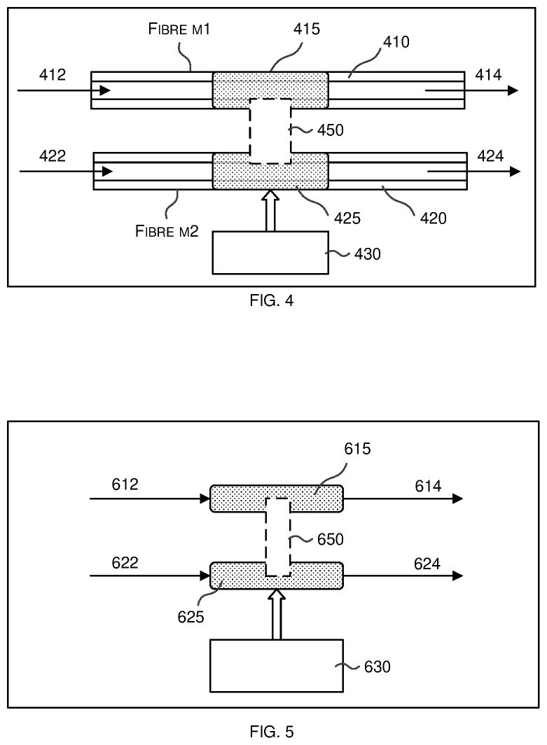

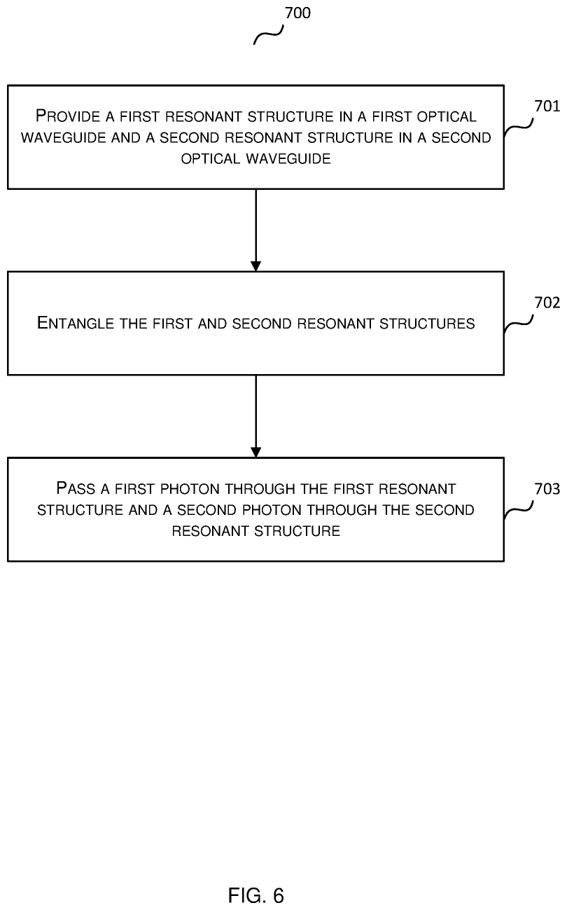

In the second example of the application, a system and method for entangling two photons is provided. This example takes advantage of the properties of the use of microscale or nanoscale resonators described above and uses the microscale or nanoscale resonators to entangle photons. FIGS. 4 shows a system for entangling two photons in waveguides comprising hollow core optical fibres. FIG. 5 shows a system for entangling two photons in waveguides comprising photonic/optical cavities fabricated on a surface of a substrate. FIG. 6 is a flowchart detailing a method for entangling two photons.

FIG. 4 shows an example system for entangling two photons wherein the photons are entangled by passing them through entangled resonant structures in/on a pair of optical waveguides. In the example shown in FIG. 4 the waveguides are a pair of hollow core optical fibres comprising a first hollow core optical fibre 410 and a second hollow core optical fibre 420. As shown in FIG. 4 light (such as a photon) is input to hollow core optical fibre 410 at arrow 412 and light is output from hollow core optical fibre 410 at arrow 414. Similarly, light (such as a photon) is input to optical fibre 420 at arrow 422 and is output from hollow core optical fibre 420 at arrow 424.

The first hollow core optical fibre 410 comprises a first micro/nano structure 415 in/on the walls of a first section of the first hollow core optical fibre 410. Similarly, second hollow core optical fibre 420 comprises a second micro/nano structure 425 in/on the walls of a second section of the second hollow core optical fibre 420. The first and second micro/nano structures 415, 425 are each configured to act as a surface acoustic wave modulator. The first and second micro/nano structures 415, 425 can be driven into an entangled state using a microwave incident signal, for example coupling field 450, from driving system 430 that excites the two resonant micro/nano structures. To this end, the first and second micro/nano structures 415, 425 are configured such that acoustic phonons are created by excitation using microwaves and so that they emit microwave photons. This enables the first and second micro/nano structures 415, 425 to be coupled and hence entangled. Methods of entangling macroscopic structures using microwaves are known. Thus, by excitation of two micro/nano structures which are resonant structures in adjacent hollow core optical fibres 410, 420, using a microwave source, the micro/nano structures can be prepared in an entangled state. As discussed above, photon-phonon mediate interactions mean that when photons pass through each of the hollow core optical fibres 410, 420, the entangled state is passed to the two photons. Therefore, by preparing the first and second micro/nano structures in an entangled state and passing a photon through each of the micro/nano structures it is possible to entangle the photons. This is because the mechanical oscillation of the micro/nano structures, which may be resonator structures, can be used to modulate the photons in the incident light signals 412 and 422.

The first and second micro/nano structure 415, 425 may be micro/nano structures as described with respect to FIG. 1. As with FIG. 1 the length of each micro/nano structure may be varied to create specific resonant frequencies in the waveguide. Some applications may use an array of varying length micro/nano structures, to provide filtering or selection of multiple frequencies in parallel. In one example, the first micro/nano structure 415 may comprise a section of the first hollow core optical fibre 410. In this example, the second micro/nano structure 425 may then comprise a section of the second hollow core optical fibre 420. The sections of the first and second hollow core optical fibres 410, 420 can be made piezoelectric, for example by having a piezoelectric layer in the hollow core optical fibres 410, 420 or by having the hollow core optical fibres 410, 420 being made, at least in part, by a piezoelectric material. The sections of the first and second hollow core optical fibres 410, 420 can then comprise a thin metal film either coating, within or inside the hollow core optical fibres 410, 420. The thin metal film can thus be internal to the fibre core or part of the outer structure. The thin metal film can take the form of an interdigital transducer and to this end may be a pattern such as interdigitated rings, or a grid which may comprise interlaced conductive elements. To this end the metal film can be patterned as an interdigital transducer. The first and second micro/nano structure 415, 425 can be driven by a microwave source to generate entanglement between the first and second micro/nano structure 415, 425. This can result in an electromagnetic coupling 450 via emitted and absorbed microwave photons. In addition, since the first and second micro/nano structure acts as an interdigital transducer, they will generate surface acoustic waves that enable phonon to photon modulation.

Thus, when a photon passes through/over the first/second micro/nano structure quantum information transfers from a phonon of the surface acoustic wave to the photon. As such, when a pair of photons pass through the entangled micro/nano structures 415, 425 (with one photon passing through each micro/nano structure) the pair of photons will become entangled, for example, entangled in frequency.

Existing hollow core optical fibres have many internal cross-section designs that vary in number and configuration of the active and cavity sections. The region of the fibre used as a micro/nano resonant structure could either be in the core hollow zone, or across the whole fibre cross-section. In addition, by applying varying lengths of metal film to sub-sections of the same fibre, in the same region, then by applying a single driving resonant signal, the fibre will resonate at multiple wavelengths in parallel. This would allow the optical signal in the fibre to have different frequencies selected, or to filter out unwanted frequencies.

In other examples, as also described with respect to FIG. 1, the first and second micro/nano structures 415, 425 may be a structured macromolecule or nanoscale crystal, a nanoscale or microscale molecular disk, rod or dot, such as a graphene flake, a carbon or boron nanotube or silicon nanowire, or a buckyball. In other examples the micro/nano structures 415, 425 may be doped metal atoms within a glass of the optical fibres 410, 420 or trapped ions or atoms inside a cavity of the optical fibres 410, 420. The first and second micro/nano structures 415, 425 may also be an anti-resonant structure within an anti-resonant nodeless fibre or a cell within a photonic crystal-based fibre. The micro/nano structures 415, 425 can be included within the sidewalls and/or cells of the hollow core optical fibres 410, 420. In some examples, the micro/nano structures 415, 425 are patterned with a metallic structure that allows acoustic phonons to be created by excitation using microwaves and may also enable the micro/nano structure to emit microwave photons. Thus, the micro/nano structures 415, 425 can act as an interdigital transducer wherein interdigital transducers convert electrical/microwave signals to surface acoustic waves and hence resonance states in the form of excitation of phonons. In other examples, the micro/nano structures 415, 425 are configured to acts as an interdigital transducer without the need for patterned metallic structure. In all examples, the micro/nano structures 415, 425 can be entangled by driving the micro/nano structures 415, 425 with microwaves. As discussed above, when a pair of photons pass through the entangled micro/nano structures 415, 425, the pair of photons become entangled.

FIG. 5 shows another example system for entangling photons in waveguides. However, in this Figure, the waveguides, comprise photonic cavities fabricated on a surface of a substrate made of a solid-state material such as silicon, germanium, lithium niobate or indium phosphide. Thus, the waveguides may comprise guided system that involves free space sections, in which lenses, diffraction gratings and collimators are used to direct light, and the light may interact with surfaces (for example reflective or refractive) which may be involved in redirecting the light.

Light in a first waveguide enters first micro/nano structure 615 at 612 and leaves at 614. Similar light in a second waveguide enters second micro/nano structure 625 at 622 and leaves at 624. The first and second micro/nano structures 615, 625 each comprise a resonator. As described with respect to FIG. 2, the length of each micro/nano structure may also be varied to create specific resonant frequencies in the waveguide. Some applications may use an array of varying length micro/nano structures, to provide filtering or selection of multiple frequencies in parallel. In addition, as described with respect to FIG. 2 each of the first and second resonator 615, 625 may be a cavity that is fabricated directly on the surface of the substrate. The resonators 615, 625 may thus be metallic coupled disks or graphene flakes which are bounded to the surface of the waveguide by nano-couplers or micro-couplers (lengths of material) or may be weakly bonded by surface forces such as Van der Walls. In other examples, the resonators 615, 625 may be structured macromolecules or nanoscale crystals such as buckyballs which may be trapped on a surface of the waveguide or within a layer of the waveguide, for example as peapod nanotubes. The first and second resonators 615, 625 act as interdigital transducers. Thus, when the resonators 615, 625 are driven by microwaves using driving system 530, surface acoustic waves, and hence phonons, are generated. As described with respect to FIG. 2, these phonons can be used to transfer information to/from photons passing through/over/under the resonators 615, 625.

As described with respect to FIG. 4, the micro/nano structures 615 and 625 can comprise, take the form of or otherwise be provided/decorated/coated with/a pattern that forms an interdigital transducer. This pattern may be a metallic pattern in the form of an interdigital transducer. However, other ways of generating surface acoustic waves may also be possible.

As mentioned with respect to FIG. 4, the first and second resonators 615, 625 can be entangled using a microwave incident signal, such as coupling field 650, from driving system 630 that excites the two resonators 615, 625. To this end, the first and second resonators 615, 625 are configured such that acoustic phonons are created by excitation using microwaves and so that they emit microwave photons. This enables the first and second resonators 615, 625 to be coupled and hence entangled. Methods of entangling macroscopic structures using microwaves are known. As discussed above, photon-phonon mediate interactions mean that when photons pass through each of the resonators 615, 625, the entangled state is passed to the two photons. Therefore, by preparing the first and second resonators 615, 625 in an entangled state and passing a photon through each of the micro/nano structures it is possible to entangle the photons.

FIGS. 4 and 5 describe micro/nano structures that may be resonators. As mentioned with respect to FIGS. 1 and 2 the micro/nano structures may be resonant structures that may be a whole or part of the cross section of the waveguide. For example, the resonant structures may be a subcomponent of the cross section of the waveguide, such as a cell within the photonic crystal, or an anti-resonant structure within the NANF. In other examples the resonant structures may be nanoscale cavities in the surface of the waveguide. In further examples, the resonant structures may be structured macromolecules or nanoscale crystals, nanoscale or microscale molecular disks, rods or dots, such as graphene flakes, carbon or boron nanotubes or silicon nanowires, or buckyballs. The resonant structures may be an inclusion within the sidewalls of the waveguide (e.g. within the cells of the hollow core structure). The resonant structures may be patterned with a metallic structure that allows acoustic phonons to be created by excitation using microwaves. This structure may also emit microwave photons. This provides a means of coupling two adjacent resonant structures and exchanging quantum information or creating entanglement between the states. The resulting system can then form part of a fibre optical system, either for communication or information processing.

As also discussed above, in order to obtain a stronger interaction between optical photons used in telecommunication systems (with wavelength typically in the range 600-1700 nm) and the mechanically resonant micro/nano structures, some implementations provide smaller features, such as nanoscale cavities. In some implementations the mechanical micro/nano structures are at the nanoscale, therefore affording stronger coupling with the optical signal. In other implementations the microscale resonator interacts with nanoscale features, for example by changing the separation of a surface pattern on the resonator, or the distribution of the cavities.

FIG. 6 is a flowchart showing a method 700 for entangling two photons using first and second micro/nano structures/resonators. In step 701 a first resonant structure is provided in a first optical waveguide and a second resonant structure is provided in a second optical waveguide. As discussed above with respect to FIGS. 4 and 5, the first and second optical waveguides may comprise hollow core optical fibres 410, 420 or photonic cavities fabricated on the surface of a substrate 610, 620. When the first and second waveguides are hollow core optical fibres 410, 420, then the resonator structures 415, 425 can comprise: a portion of each of the hollow core optical fibres 410, 420 that has, optionally, been adapted to have piezoelectric properties and which is patterned with a metallic film; structured macromolecules or nanoscale crystals nanoscale or microscale molecular disks, rods or dots, such as a graphene flakes; carbon or boron nanotubes or silicon nanowires; buckyballs; doped atoms within a glass of the optical fibres 410, 420; or trapped ions or atoms inside a cavity of the optical fibres 410, 420. When the waveguides are photonic cavities fabricated on the surface of a substrate, then the resonant structures can comprise structured macromolecules or nanoscale crystals, cavities that are fabricated directly on the surface of each waveguide such as metallic coupled disks or graphene flakes or buckyballs which may be trapped on a surface of each the waveguides or within a layer of each of the waveguides.

At step 702, the method comprises entangling the first and second resonant structures. The first and second resonant structure may be entangled by driving the first and second resonant structures using microwave frequency photon stimulation. The first and second resonant structure may thus be in the form of interdigital transducers or may each be provided with a metallic pattern that takes the form of an interdigitated transducer. The interdigital transducers generate surface acoustic waves in the first and second resonant structure which can then be used to generate entanglement. The entanglement of macroscopic structures using microwaves is known.

At step 703, a first photon is passed through the first resonant structure and a second photon is passed through the second resonant structure. In some examples, and depending on the form of the resonant structures, the first/second photon may be passed over or under the first/second resonant structure. In other examples, the first/second photon can be reflected from a surface of the first/second resonant structure rather than passing through the first/second resonant structure. Since the first and second resonant structures are in an entangled state due to surface acoustic waves/microwave frequency photon stimulation, when the first photon is passed through the first resonant structure and the second photon is passed through the second resonant structure, the entangled state from the resonant structures is transferred to the photons.

This results in the first and second photon becoming entangled, for example in frequency. This could be used to generate two-qubit gates in photonic quantum computing. This also enables the generation of entangled photons for use in quantum communication and quantum cryptographic systems. In particular, the mechanical oscillations of the first and second resonant structure can be used to modulate the incoming photons (or incident light signals).

As describes above, in some examples the resonant structures can be based on the standard form of interdigital transducer electrodes (IDT). These generate a surface acoustic wave within the glass structure of the fibre in the locality of the IDT. Provided the resonant structures have been driven into an entangled state: then the pair of light signals should become entangled in frequency. Depending on the relative phase and amplitude of the photons/light signals the outputs may either have f2 frequency shifted to match f1, or some heterodyne frequency combination may be generated as required.

While the above has focused on a pair of quantum entangled resonators, in other examples a variable number of resonators to achieve multi signal modulation. In addition, the skilled person would understand that in all above examples, with present micro-entanglement processes, the main hardware (i.e. the waveguides and micro/nano structures) may need to be cryogenically cooled to achieve a stable quantum entangled state. However, the invention should not exclude high temperature superconducting systems which may operate at ambient temperatures or the use of nano-scale structures such as graphene.

Given the above, in this application, a waveguide such as hollow-core fibre optic system may also be utilised as a nano-scale mechanical resonant structure. By coating the fibres in a thin metal film or a structured coating, incident microwaves can be used to induce an entangled quantum state, across two or more coupled fibres. The quantum entangled state can also be induced in pure glass fibres, or by doping the fibres with suitable atomic dopants. In some examples the metallic film can be metallic pattern, such as an interdigitated rings, or a grid which may consist of interlaced conductive elements. This may require substrate which is piezo-electric. Therefore, a piezo-electric layer may be applied to the waveguide, or a piezoelectric material may be used in the waveguide. The target area would be a short length of the fibre where two or more fibres would be in sufficient proximity for the entanglement to occur. The coating may also be internal to the fibre design. In some implementations, the photons passing through each fibre will experience a wavelength or phase modulation driven by the phonic oscillation of the target length of fibre. By varying the driving signal frequency of the resonators, it should then be possible to modulate the wavelength of the transmitted photons. A signal laser providing the photons or other photon source may also be reflected from the surface of the micro resonator, rather than passing through the resonant cavity.

Also described in the application, an alternative to the use of hollow core optic fibre, is optical cavity structures that are fabricated directly on the surface of a silicon substrate, such that the cavities can be driven into a quantum entangled state. The input photons then pass through the pair of resonant metal cavities before being output into fibre. Known techniques for interfacing laser pulses from fibre into silicon layers could then be used to introduce the signals for entanglement and photon-phonon coupling. A signal laser providing the photons or other photon source may also be reflected from the surface of the micro resonator, rather than passing through the resonant cavity.

In one detailed example, a micro-structured surface may be a programmable meta-surface with features small enough to give a strong mechanical (acousto-optic) interaction with the photons. These may be nanoscale cavities in the wall of the waveguide (e.g. hollow core fibre) which are excited into phononic states by the exchange of both energy and quantum information from the photons, which technically speaking may be optical or acoustic phonons, but in most implementations will be acoustic (long wavelength) phonons. The waveguide may be a hollow core fibre or may incorporate free space collimated beams directed between directing (reflecting, refracting and/or focusing/collimating) surfaces and structures. These structures may be nanoscale cavities, or nano or microscale resonators. For example metallic coupled disks or graphene flakes which may be bonded to the surface of the waveguide by nano-couplers or micro-couplers (lengths of material) or may be weakly bonded by surface forces such as Van der Waals. In some examples the resonating structures may be structured macromolecules or nanoscale crystals such as buckyballs which may be trapped on the surface of the waveguide, or within a layer of the waveguide (for example as peapod nanotubes). This result in the interaction between the beam carrying photons and the surface of the waveguide which exchanges quantum information between the photons and quantum states in the surface of the waveguide. The state may act as a quantum memory. Releasing the quantum information from the micro-resonator may involve stressing the material using an applied electric field, magnetic field or mechanical deformation e.g. via a piezo-electric element within the surface, which changes the properties of the resonator, causing the release of the quantum state when stimulated by an incident photon which is travelling through the waveguide. The above mechanisms may also be used to tune the wavelength (and equivalently frequency) of the photon that the structure/surface interacts with. Therefore, a selective interaction between different channels (wavelengths) within the same medium/waveguide may be programmed. In this way, the quantum memory may be used to interact with selected channels. Alternatively, a photon carrying a qubit/qudit of quantum information may interact with the surface mechanical resonance qubit/qudit state, resulting in entanglement between the quantum state on the surface and the quantum state being propagated by the photon. In this way, the quantum information may be read out from the static resonators, which act as memories, into a moving quantum information stream. This may have applications in quantum repeaters for QKD (quantum key distribution). Furthermore, resonators in adjacent waveguides may be coupled together using microwaves. These microwaves may be generated using interdigitated links or other metallic or semi-metallic patterned structures embedded within a piezoelectric substrate. Coupling is therefore possible, and at low temperatures or under other conditions which allow rejection of stray thermal microwave photons, it will be possible for a resonator in a superposition of states to excite a microwave which is in a superposition of states, which will further interact with a second resonator and excite the second resonator into a superposition of states. In this way, quantum information may be transferred between resonators in adjacent waveguides using a coupling field, such as a microwave field. Secondly, an applied microwave field may be used to prepare two resonators in the same or separate waveguides into a superposition of states.

The above examples utilise the phenomena of quantum mechanical resonators to store, and exchange to quantum information with optical signals. By utilising a micro-scale quantum entanglement effect, where a classical-scale pair of objects become entangled, the dimensions of the objects make it possible for them to interact with an optical signal within standard fibre optic systems. The application proposes two methods for achieving the effect: either using on chip fabricated resonators or using a hollow core fibre optics. The application has a broad range of applications from data communication and QKD (quantum key distribution) systems, to quantum information processing. The use of embedded etched SAW (surface acoustic wave) structures in hollow core fibres could also be utilised without exploiting quantum entangling effects or cryogenic temperatures.

The above-described examples may have several advantages. For example the above-described examples, may enable novel optical computing applications, where either frequency modulation, or the entanglement of photons is required. Specifically, if the hollow fibre method is utilised, the process can be easily integrated with existing fibre optic systems at low cost. In addition, the above-describes examples may result in improved generation of entangled photons, improved accuracy of optical frequency modulation, flexible fabrication options, either on silicon or in fibre, and applications in QKD (quantum key distribution) systems. Further potential advantages include ultra-precise optical frequency control of photonic signals and quantum information processing applications.

Any reference to ‘an’ item refers to one or more of those items. The term ‘comprising’ is used herein to mean including the method blocks or elements identified, but that such blocks or elements do not comprise an exclusive list and an apparatus may contain additional blocks or elements and a method may contain additional operations or elements. Furthermore, the blocks, elements and operations are themselves not impliedly closed.

The steps of the methods described herein may be carried out in any suitable order, or simultaneously where appropriate. The arrows between boxes in the figures show one example sequence of method steps but are not intended to exclude other sequences or the performance of multiple steps in parallel. Additionally, individual blocks may be deleted from any of the methods without departing from the spirit and scope of the subject matter described herein. Aspects of any of the examples described above may be combined with aspects of any of the other examples described to form further examples without losing the effect sought. Where elements of the figures are shown connected by arrows, it will be appreciated that these arrows show just one example flow of communications (including data and control messages) between elements. The flow between elements may be in either direction or in both directions.

Where the description has explicitly disclosed in isolation some individual features, any apparent combination of two or more such features is considered also to be disclosed, to the extent that such features or combinations are apparent and capable of being carried out based on the present specification as a whole in the light of the common general knowledge of a person skilled in the art, irrespective of whether such features or combinations of features solve any problems disclosed herein. In view of the foregoing description it will be evident to a person skilled in the art that various modifications may be made within the scope of the invention.

While the above description focuses on the use of microwave driving signals, one skilled in the art will appreciate that other driving signals (i.e. external excitations) may additionally or alternatively be used to cause phonic oscillation (e.g. resonant acoustic waves applied external to the optical waveguide). Similarly, while the above description refers to the use of metallic films within the hollow core optical fibre, it should be understood that alternative types of film (such as solid state films) may also be used to allow acoustic phonons to be created by excitation.

It should be further understood that the term “phonic oscillation” as used herein may also be called “phononic oscillation” and refers to quantum mechanical vibrations of the resonant structure.

1. A method of exchanging quantum information between a photon and a micro/nano scale resonant structure, the method comprising:
providing the resonant structure in an optical waveguide;
passing a photon through the resonant structure in the optical waveguide; and
applying a driving signal to the resonant structure to cause phonic oscillation of the resonant structure and to modulate a wavelength of the photon such that the passing the photon through the resonant structure results in an exchange of quantum information between the photon and a quantum state in a phonon of the resonant structure.

2. The method of claim 1 wherein:
the optical waveguide is a hollow core optical fibre; and
the resonant structure comprises a section of the hollow core optical fibre wherein the section of the hollow core optical fibre comprises a film wherein the film either coats or is internal to the section of the hollow core optical fibre and wherein the film allows acoustic phonons to be created by excitation.

3. The method of claim 2 wherein:
the hollow core optical fibre comprises a piezoelectric material or the hollow core optical fibre comprises a piezoelectric layer;
the film is a metallic film;
the metallic film allows acoustic phonons to be created by excitation using microwaves; and optionally
wherein the metallic film is a surface acoustic wave modulator in the form of an interdigital transducer.

4. The method of claim 1 wherein:
the optical waveguide is a photonic cavity fabricated on a surface of a substrate; and
the resonant structure is a cavity fabricated on the surface of the substrate.

5. The method of claim 1 further comprising:
stressing the resonant structure using an applied electric field, magnetic field or mechanical deformation to change the properties of the resonant structure; and
passing a second photon through the resonant structure wherein passing the second photon through the resonant structure causes release of the quantum state stored in the resonant structure.

6. The method of claim 1, wherein the driving signal is a microwave driving signal.

7. A system comprising:
an optical waveguide;
a micro/nano scale resonant structure within the optical waveguide; and
a driving system configured to apply a driving signal to the resonant structure and cause phonic oscillation of the resonant structure and thus modulate a wavelength of a photon passing through the resonant structure and hence exchange quantum information between the photon and a quantum state in a phonon of the resonant structure.

8. The system of claim 7 wherein:
the optical waveguide is a hollow core optical fibre; and
the resonant structure comprises a section of the hollow core optical fibre wherein the section of the hollow core optical fibre comprises a film wherein the film either coats or is internal to the section of the hollow core optical fibre and wherein the film allows acoustic phonons to be created by excitation.

9. The system of claim 8 wherein:
the hollow core optical fibre comprises a piezoelectric material or the hollow core optical fibre comprises a piezoelectric layer;
the film is a metallic film;
the metallic film allows acoustic phonons to be created by excitation using microwaves; and optionally
wherein the metallic film is a surface acoustic wave modulator in the form of an interdigital transducer.

10. The system of claim 7 wherein:
the optical waveguide is a photonic cavity fabricated on a surface of a substrate; and
the resonant structure is a cavity fabricated on the surface of the substrate.

11. A method of entangling two photons, the method comprising:
providing a first micro/nano scale resonant structure in a first optical waveguide;
providing a second micro/nano scale resonant structure in a second optical waveguide;
entangling the first and second resonant structures;
passing a first photon through the first resonant structure of the first optical waveguide; and
passing a second photon through the second resonant structure of the second optical waveguide.

12. The method of claim 11 wherein entangling the first and second resonant structures comprises driving the first and second resonant structures via microwave frequency photon stimulation.

13. The method of claim 11 wherein:
the first optical waveguide is a first hollow-core optical fibre;
the second optical waveguide is a second hollow-core optical fibre;
the first resonant structure comprises a first section of the first hollow core optical fibre wherein the first section of the first hollow core optical fibre comprises a first film wherein the first film either coats or is internal to the first section of the first hollow core optical fibre and wherein the first film allows acoustic phonons to be created by excitation;
the second resonant structure comprises a second section of the second hollow core optical fibre wherein the second section of the second hollow core optical fibre comprises a second film wherein the second film either coats or is internal to the second section of the second hollow core optical fibre and wherein the second film allows acoustic phonons to be created by excitation.

14. The method of claim 13 wherein:
the first and second hollow-core optical fibres comprise a piezoelectric material or the first and second hollow-core optical fibres comprise a piezoelectric layer;
the first film is a first metallic film wherein the first metallic film allows acoustic phonons to be created by excitation using microwaves;
the second film is a second metallic film wherein the second metallic film allows acoustic phonons to be created by excitation using microwaves; and optionally
the first metallic film and the second metallic film are surface acoustic wave modulators in the form of interdigital transducers.

15. The method of claim 11 wherein:
the first optical waveguide is a first optical cavity structure fabricated on a surface of a substrate;
the second optical waveguide is a second optical cavity structure fabricated on the surface of the substate;
the first resonant structure is a first metal cavity in the first optical cavity structure; and
the second resonant structure is a second metal cavity in the second optical cavity structure.

16. A system comprising:
a first optical waveguide;
a second optical waveguide;
a first micro/nano scale resonant structure in the first optical waveguide;
a second micro/nano scale resonant structure in the second optical waveguide; and
a driving system configured to apply an incident signal to the first resonant structure and the second resonant structure and hence excite and entangle the first and second resonant structures.

17. The system of claim 16 wherein:
the first optical waveguide is a first hollow-core optical fibre;
the second optical waveguide is a second hollow-core optical fibre;
the first resonant structure comprises a first section of the first hollow core optical fibre wherein the first section of the first hollow core optical fibre comprises a first film wherein the first film either coats or is internal to the first section of the first hollow core optical fibre and wherein the first film allows acoustic phonons to be created by excitation;
the second resonant structure comprises a second section of the second hollow core optical fibre wherein the second section of the second hollow core optical fibre comprises a second film wherein the second film either coats or is internal to the second section of the second hollow core optical fibre and wherein the second film allows acoustic phonons to be created by excitation.

18. The system of claim 17 wherein:
the first and second hollow-core optical fibres comprise a piezoelectric material or the first and second hollow-core optical fibres comprise a piezoelectric layer;
the first film is a first metallic film wherein the first metallic film allows acoustic phonons to be created by excitation using microwaves;
the second film is a second metallic film wherein the second metallic film allows acoustic phonons to be created by excitation using microwaves; and optionally
the first metallic film and the second metallic film are surface acoustic wave modulators in the form of interdigital transducers.

19. The system of claim 16 wherein:
the first optical waveguide is a first optical cavity structure fabricated on a surface of a substrate;
the second optical waveguide is a second optical cavity structure fabricated on the surface of the substate;
the first resonant structure is a first metal cavity in the first optical cavity structure; and
the second resonant structure is a second metal cavity in the second optical cavity structure.

20. The system of claim 16 wherein:
the first resonant structure is a micro-scale resonant structure and a first surface of the first micro-scale resonant structure is decorated with nano-scale features; and
the second resonant structure is a micro-scale resonant structure and a second surface of the second micro-scale resonant structure is decorated with nano-scale features.
